(19) United States
(12) Patent Application Publication
(10) Pub. No.: US 2004/0060173 A1
(43) Pub. Date: Apr. 1, 2004

(54) Method for producing interconnection in a multilayer printed circuits

(76) Inventors: Bernard Ledain, Sevres (FR); Sylvie Secher, Villiers St Frederic (FR); Philippe Kertesz, Rueil Malmaison (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/451,258

(22) PCT Filed: Dec. 11, 2001
(86) PCT No.: PCT/FR01/03929

(30) Foreign Application Priority Data
Dec. 21, 2000 (FR) 00/16776

(51) Int. Cl. H05K 3/46

(52) U.S. Cl. 29/830; 29/852

(57) ABSTRACT

The present invention relates to a process for producing interconnects in a multilayer printed circuit. Said circuit comprising a stack of printed circuits. The process is carried out according to the following steps:

a step of producing plated holes in elementary printed circuits;

a step in which the holes and the elements to which they have to be electrically connected are covered with a metallic interface (61, 62);

a step in which the metallic interfaces (61, 62) are covered with a component of a metal alloy, the metallic interface (61) of a hole being covered with a first component (71) and the metallic interface (62) of the element to be electrically connected to this hole being covered with a second component (72), these two metallic components (71, 72) being brought into contact with each other while pressure is being exerted on the stack in order to form the multilayer printed circuit;

a step (73) of heating the assembly.

The invention applies, for example, to digital circuits having a high integration density or to microwave circuits.

The present invention relates to a process for producing interconnects in a multilayer printed circuit. It applies, for example, to digital circuits having a high integration density or to microwave circuits.

It is known to produce interconnects in multilayer printed circuits that provide electrical connections between various layers of the circuit. A first solution consists in drilling plated holes through the entire thickness of the printed circuit. Such a solution has at least two drawbacks. Firstly, it takes up space. For example, to electrically connect the third layer to the fourth layer of a circuit, it is nevertheless necessary to drill right through the entire thickness of the printed circuit and therefore to reduce the area available on the other layers. This problem is even more sensitive when the circuit comprises a large number of layers, since reliability constraints mean that the diameter of the holes has to be increased when their length is increased. In the case of multilayer circuits comprising digital functions, the space required may be a very important parameter to be taken into account, especially because of the increasingly severe integration constraints.

A second drawback specific to these plated holes is their antenna effect, which may be especially problematic if the circuit includes microwave functions. This effect may possibly be eliminated by producing buried holes, that is to say by pressing a printed circuit on each side of the multilayer circuit in order to close off the holes.

One solution, optimized both from the standpoint of space requirement and the antenna effect, is to produce plated holes only between the layers to be connected. If we consider the above example, this amounts to creating a plated hole only between the third and fourth layers, or else between a second and a fourth layer for example. For this purpose, plated holes may simply be produced in each of the layers before they are joined together to form the multilayer circuit, each layer being in fact a single double-sided printed circuit. Thus, again taking the above example, a plated hole is produced in the third layer. A tricky problem to be solved is then in particular how to ensure a reliable electrical contact between the plated hole and the elements to which it is connected, these elements possibly being, for example, another plated hole, a conducting track or a conducting plane.

It is an object of the invention in particular to allow the production of a multilayer printed circuit as described above with reliable electrical contacts at the outlets of the plated holes of the internal layers. For this purpose, the subject of the invention is a process for producing interconnects in a multilayer printed circuit comprising a stack of elementary printed circuits, the process being carried out according to the following steps:

a step of producing plated holes in elementary printed circuits;

a step in which the holes and the elements to which they have to be electrically connected are covered with a metallic interface;

a step in which the metallic interfaces are covered with a component of a metal alloy, the metallic interface of a hole being covered with a first component and the metallic interface of the element to be electrically connected to this hole being covered with the second component of the alloy, these two metallic components being brought into contact with each other while pressure is being exerted on the stack in order to form the multilayer printed circuit;

a step of stacking the elementary printed circuits; and

a step of heating the assembly in order to end up with the diffusion of the metallic components, where the metallic interfaces diffuse into the metallic components, the temperature at which these components diffuse being below the melting point of the metallic component that is obtained after cooling and forms the electrical connection.

Advantageously, the components of the alloy are silver and tin, or else indium and tin, which make it possible to obtain a melting point of the metallic compound forming the electrical connections that is substantially above their melting points.

Other features and advantages of the invention will become apparent from the description that follows, in conjunction with the appended drawings which show:

FIG. 1, an example of an interlayer connection by a plated hole passing completely through the multilayer printed circuit;

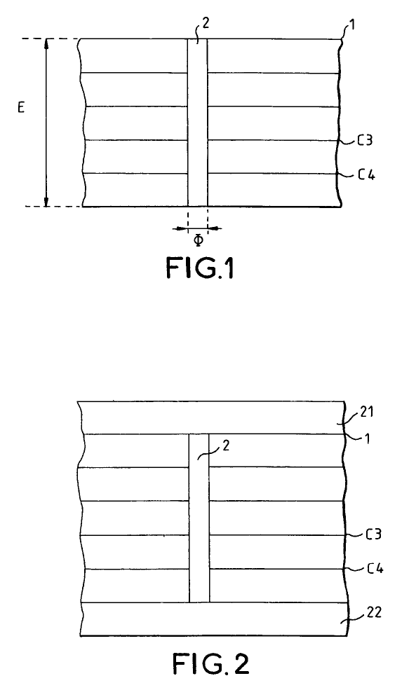

FIG. 2, an example of an interlayer interconnect produced by a buried plated hole;

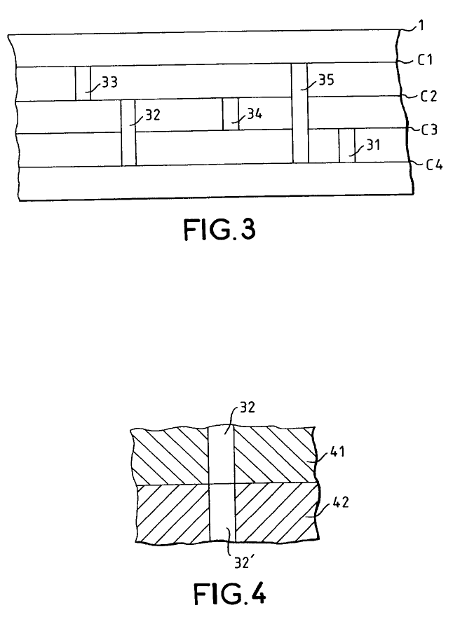

FIG. 3, an example of interconnects between the layers of a printed circuit in which the plated holes are drilled between the layers to be connected;

FIG. 4, a connection between two plated holes of facing printed circuits;

FIG. 5, a step of the process according to the invention in which the plated holes are drilled and plated beforehand in elementary printed circuits forming the multilayer printed circuit;

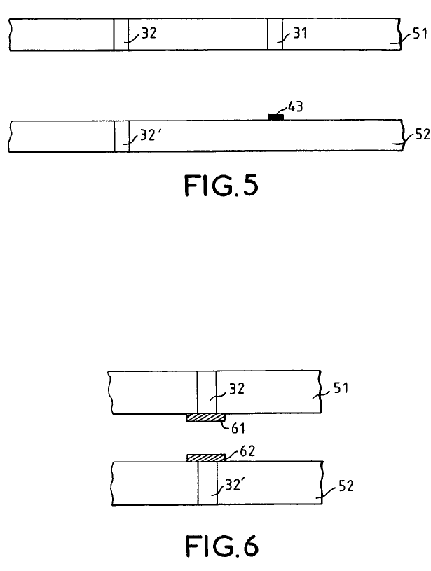

FIG. 6, another step of the process according to the invention in which holes to be electrically connected are covered with a metallic interface; and

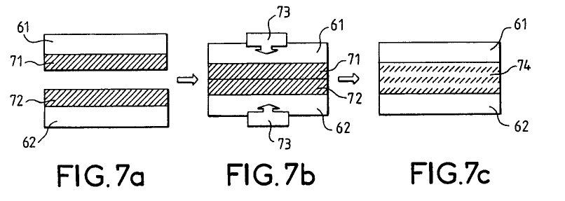

FIGS. 7a, 7b and 7c, an illustration of the formation of the electrical contact by interdiffusion of a deposit between the aforementioned metallic interfaces.

FIG. 1 therefore shows, in a partial sectional view, a multilayer printed circuit 1. This circuit has a plated hole 2 running right through this circuit. Conventionally, this plated hole electrically connects, for example, elements of the third layer C3 to the fourth layer C4. For this purpose, conducting tracks or ground planes supported by these layers C3, C4 are, for example, penetrated by this plated hole. A drawback of this type of connection is that the plated hole 2 occupies an extraneous area on the other layers, which poses a space problem. Moreover, the greater the thickness E of the circuit, the larger the diameter Φ of the hole 2, especially for reliability reasons. In other words, the Φ/E ratio must not fall below a minimum threshold. Typically, this ratio is, for example, between 5 and 10. Thus, the thicker a multilayer circuit, the more area wasteful the plated hole 2. Finally, this plated hole has an antenna effect which may be especially detrimental when the circuit 1 has a microwave function or when it operates in a microwave environment.

FIG. 2 shows an example of a connection which makes it possible in particular to eliminate the antenna effect. In this case, a layer 21, 22, that is to say in fact a monolayer circuit, closes off the holes 2 on either side of a multilayer printed circuit 1 produced as in the case of FIG. 1. However, such a circuit with buried holes does not solve the space problem. Moreover, it does not always eliminate the antenna effect.

FIG. 3 shows a method of connection that reduces the space occupied by the presence of the plated holes. In this case, the plated holes 31, 32, 33, 34, 35 pass through only the layers between the connection points to be provided. Thus, a hole 31 electrically connecting the third layer C3 to the fourth layer C4 passes only through the space between these two layers. A plated hole 32 electrically connecting the second layer C2 to the fourth layer C4 passes through the space between these two layers—possibly only the third layer C3 loses space because of the passage of the hole. To produce internal plated holes as described by FIG. 3, it is firstly simple to drill these holes in the constituent layers of the printed circuit before these layers are joined together. In fact, these layers are single-sided or double-sided printed circuits. Once the holes have been drilled and plated in a conventional manner in all these elementary printed circuits, the latter have to be joined together, more particularly pressed and heated in order to form the multilayer printed circuit.

FIG. 4 illustrates an electrical connection between a first hole 32 drilled in an elementary printed circuit 41 and a second hole 32′ drilled in the adjacent elementary printed circuit 42 in the case of a printed circuit as illustrated by FIG. 3. The electrical contact between these two holes must be reliable. In particular, this electrical contact must withstand conventional printed-circuit validation tests, such as especially impact tests at temperatures, that is to say for example cycles in which the temperature is rapidly varied between −65° C. and +150° C. It should be noted that if a conventional production process is used, the electrical contact between the two holes 32, 32′ must withstand high temperatures during bonding of these two elements 32, 32′. In a conventional process, this bonding requires temperatures of about 700° C. to 800° C. and is carried out under high pressure. The reliability of the electrical connection does not arise only in the case of the connection of two plated holes but also in the case of the connection of a plated hole with, for example, a conducting pad. In a printed circuit of the type in FIG. 1 for example, the connecting plated holes 2 pass through the conducting pads of the internal layers to be connected. Because they pass through these pads, this ensures a reliable electrical contact. In the case of a circuit of the type in FIG. 3, given that the connecting plated holes no longer pass through the conducting pads to be connected, measures have also to be taken to ensure that there is a reliable electrical contact between the end of a hole 32 and a conducting pad onto which this hole opens out. The process according to the invention makes it possible to produce reliable electrical contacts, which in particular withstand the abovementioned constraints.

FIG. 5 therefore illustrates a first possible step of the process according to the invention. In this first step, plated holes 31, 32, 32′ are produced in each of the elementary printed circuits 51, 52 forming the multilayer printed circuit. To simplify the illustration, only two elementary layers or printed circuits 51, 52 have been shown in FIG. 5. Apart from the plated holes, the other constituent elements of the circuit are also involved, such as for example the internal tracks or access pads 43. The plated holes 31, 32, 32′ are produced in a conventional manner in the elementary printed circuits 51, 52. For this purpose, the latter are, for example, prior to drilling, covered with a copper layer. An electrical insulator (not shown) is for example inserted between the copper layers, which insulator, drilled beforehand, will also be used as bonding layer. The copper is then removed at certain points so as to leave only metal tracks, pads or planes. Once the elementary circuits 51, 52 have therefore been drilled with connecting holes 31, 32, 32′ and provided with their metallized tracks or pads, they are ready for the next steps of the process according to the invention. In the example in FIG. 5, two holes 32, 32′ are to be connected together and a hole 31 is to be connected to a metallized pad 43.

FIG. 6 shows, in the following step, two elements to be electrically connected, for example two plated holes 32, 32′. These plated holes are covered with a metallic interface, for example a metal pad 61, 62 placed at their openings that are to be connected. These metal pads 61, 62 are, for example, made of copper. The pads 61, 62 are for example obtained by etching the copper layer placed initially on their printed circuit.

FIGS. 7a, 7b and 7c illustrate the next steps of the process according to the invention, more particularly the operation of bonding the elements to be connected. For the sake of clarity, the holes have not been shown—only the metallic interfaces 61, 62 are shown. In the step illustrated by FIG. 7a, the metallic interfaces 61, 62 are each covered with a component of a metal alloy, a metallic interface 61 being covered with a first component 71 and the other metallic interface 62 being covered with the second component 72 of the alloy, and these two metallic components 71, 72 will be brought into contact with each other in the subsequent steps 7b, 7c when pressure is exerted on the stack in order to form the multilayer printed circuit. Pressure is therefore exerted on this stack while raising its temperature so as to create solid-solid diffusion between these components in order to form a stable intermetallic compound and solid-solid diffusion of the metallic interfaces toward the components of the alloy. Ideally, diffusion takes place without any melting of the metals so as in particular to avoid short circuits.

The diagrams in FIGS. 7a, 7b and 7c show this process in detail. Only the metallic interfaces 61, 62 each covered with a metal layer 71, 72 have been shown. Each metal layer forms one component of the alloy. FIG. 7a therefore shows the two metallic interfaces 61, 62 each covered with one of the components 71, 72 of the alloy before the two elementary printed circuits are pressed together.

FIG. 7b shows that the two metals making up the alloy are pressed against each other. At this stage, all the layers are pressed against one another. The temperature of the printed circuit is then raised under pressure. This results in particular in a heat flux 73 flowing toward the metal layers 71, 72. Owing to the effect of the heat, the latter start to diffuse. Advantageously, the temperature at which the components of the alloy diffuse is low, for example around 200° C. for example. There is therefore solid-solid diffusion of the metallic interface into the alloy to form a stable intermetallic compound 74 as illustrated in FIG. 7c. Advantageously, this compound is thermally stable at a very high temperature, which may for example be up to 600° C. or higher, although the process according to the invention does not require a high temperature. This is because it may, for example, be carried out at temperatures of 200° C., corresponding in fact to the temperature at which the alloy diffuses. In fact, the melting point of the compound 74 forming the electrical connection is advantageously very much higher than the temperatures at which the metals 71, 72 of the alloy diffuse. The electrical contact produced by this intermetallic compound is therefore very reliable. In particular, it may withstand severe thermal conditions.

An adhesive bonding layer (not shown) is placed between each elementary printed circuit in order for these circuits to be adhesively bonded together. Bonding takes place under the effect of the heat. This layer is especially drilled at the electrical contacts to be produced between layers.

Preferably, the alloy is, for example, a silver-tin (Ag/Sn) alloy. That is to say that one metallic interface 61 is covered with a tin layer 71 and the other metallic interface 62 is covered with a silver layer. These layers are placed only at the points of the electrical contacts to be produced. In particular, it is necessary to prevent alloy residues from remaining, which residues would not withstand in particular the high temperatures, because of the relatively low melting point of the alloy. Other alloy types are possible—for example, it is possible to use an indium-tin (In/Sn) alloy. Likewise, the copper metallic interface may be replaced with a gold metallic interface.

The parameters to be regulated are in particular the pressure and the temperature of assembly. The duration of the layer assembly process for forming a multilayer printed circuit is similar to that for the fabrication of a multilayer circuit according to a conventional process. It may be necessary to optimize the diameter of the metal pads 61, 62, 71, 72 of the plated holes so as to ensure that there is good contacting while the circuit is being pressed. The prior treatment of the layers before assembly is also to be treated with caution. This is because the low-melting-point metals that are used, for example silver, tin or indium, can rapidly oxidize. It may therefore be necessary to use a suitable means for limiting this phenomenon, or else run the risk of obtaining a bonding defect arising from a lack of wetting. It is also important to control the thickness of the metal deposits.

The process according to the invention makes it possible to obtain a reliable interconnect at the pads of the plated holes. In particular, it makes it possible to dispense with plated holes passing completely through the multilayer printed circuits. This is because, in a conventional circuit, these holes place a limit on the integration, in particular in the case of digital circuits. The elementary printed circuits forming the multilayer circuit may be single-sided or double-sided.

1. A process for producing interconnects in a multilayer printed circuit, characterized in that, said circuit comprising a stack of elementary printed circuits (51, 52), it comprises:
a step of producing plated holes (31, 32) in elementary printed circuits;
a step in which the holes (31, 32) and the elements (32′, 43) to which they have to be electrically connected are covered with a metallic interface (61, 62);
a step in which the metallic interfaces (61, 62) are covered with a component of a metal alloy, the metallic interface (61) of a hole being covered with a first component (71) and the metallic interface (62) of the element to be electrically connected to this hole being covered with the second component (72) of the alloy, these two metallic components (71, 72) being brought into contact with each other while pressure is being exerted on the stack in order to form the multilayer printed circuit;
a step of stacking the elementary printed circuits; and
a step (73) of heating the assembly, to a temperature at least equal to the temperature at which the components of the alloy diffuse but below their melting points, in order to end up with the solid-solid diffusion of the metallic components (71, 72), where the metallic interfaces (61, 62) diffuse into the metallic components, the temperature at which these components diffuse being below the melting point of the metallic component (74) that is obtained after cooling and forms the electrical connection.

2. The process as claimed in claim 1, characterized in that the heating temperature is of the order of 200° C.

3. The process as claimed in either of claims 1 and 2, characterized in that the components (71, 72) of the alloy are silver and tin.

4. The process as claimed in either of claims 1 and 2, characterized in that the components (71, 72) of the alloy are indium and tin.

5. The process as claimed in one of the preceding claims, characterized in that the metallic interfaces (61, 62) are made of copper.

6. The process as claimed in any one of claims 1 to 4, characterized in that the metallic interfaces are made of gold.

7. The process as claimed in any one of the preceding claims, characterized in that the element to be electrically connected to a plated hole is another plated hole.

8. The process as claimed in any one of the preceding claims, characterized in that a bonding layer is placed between each elementary printed circuit (51, 52), this layer being drilled at the electrical contacts to be produced.
